(19) United States
(12) Patent Application Publication
(10) Pub. No.: US 2018/0052477 A1
(43) Pub. Date: Feb. 22, 2018

(54) LOW VOLTAGE BANDGAP REFERENCE GENERATOR

(71) Applicant: MEDIATEK Singapore Pte. Ltd., Solaris (SG)

(72) Inventor: Uday Dasgupta, Singapore (SG)

(73) Assignee: MEDIATEK Singapore Pte. Ltd., Solaris (SG)

(21) Appl. No.: 15/439,621

(22) Filed: Feb. 22, 2017

Related U.S. Application Data
(60) Provisional application No. 62/376,933, filed on Aug. 19, 2016.

(51) Int. Cl. G05F 1/575; H03K 19/0185

(52) U.S. Cl. CPC G05F 1/575; H03K 19/018507

(57) ABSTRACT

A reference voltage generator circuit having a feedback circuit connected to an output branch. The circuit has a first branch, having a first current and a first voltage, a second branch, having a second current and a second voltage, and a third branch, having a third current and a third voltage. The circuit has an amplifier that couples the first voltage to the second voltage. The circuit also has a feedback circuit that couples the third voltage to at least one of the first or second voltages.

### CROSS-REFERENCE TO RELATED APPLICATIONS

This application claims priority to U.S. provisional application Ser. No. 62/376,933, filed Aug. 19, 2016, titled “Low Voltage Band-Gap,” which is hereby incorporated by reference in its entirety.

### BACKGROUND

### 1. Technical Field

The techniques described herein relate generally to bandgap reference voltage generators.

### 2. Discussion of the Related Art

Bandgap reference voltage generators are widely used in integrated circuits as a way to provide a constant voltage reference. Bandgap reference voltage generators are designed to produce a fixed voltage despite power supply variations, temperature fluctuations, fabrication tolerances, and variable loading conditions.

### SUMMARY

Some embodiments relate to reference voltage generator circuit. The circuit has a first branch, having a first current and a first voltage, a second branch, having a second current and a second voltage, and a third branch, having a third current and a third voltage. The circuit has an amplifier that couples the first voltage to the second voltage. The circuit also has a feedback circuit that couples the third voltage to at least one of the first or second voltages.

Some embodiments relate to a reference voltage generator circuit including: a first branch having a first transistor, a first impedance in series with the first transistor and a first terminal between the first transistor and the first impedance; a second branch having a second transistor, a second impedance in series with the second transistor and a second terminal between the second transistor and the second impedance; a third branch having a third transistor, a third impedance in series with the third transistor, a fourth transistor coupled between the third transistor and the third impedance and a third terminal coupled between the third transistor and the fourth transistor; a first amplifier having: a first input coupled to the first terminal; a second input coupled to the second terminal; and a first output coupled to respective control terminals of the first, second and third transistors; a second amplifier having: a first input coupled to the third terminal; and a second input coupled to the first terminal or the second terminal; and a second output coupled to a control terminal of the fourth transistor.

The foregoing summary is provided by way of illustration and is not intended to be limiting.

### BRIEF DESCRIPTION OF DRAWINGS

In the drawings, each identical or nearly identical component that is illustrated in various figures is represented by a like reference character. For purposes of clarity, not every component may be labeled in every drawing. The drawings are not necessarily drawn to scale, with emphasis instead being placed on illustrating various aspects of the techniques and devices described herein.

FIG. 1 shows a bandgap reference voltage generator.

FIG. 2 shows an embodiment of a bandgap reference voltage generator with an additional transistor and amplifier.

FIG. 3 shows another embodiment of the circuit of FIG. 2 with alternate electrical connections.

FIG. 4 shows another embodiment of the circuit of FIG. 2 with additional impedance components.

FIG. 5 shows another embodiment of the circuit of FIG. 2 with an additional output stage.

FIG. 6 shows another embodiment of the circuit of FIG. 5 with a third output stage.

### DETAILED DESCRIPTION

A bandgap voltage reference may be an important part of many integrated circuit solutions. Bandgap voltage references are ideally independent of power supply voltage, fabrication tolerances, and temperature. However, with modern transistors being scaled-down in size, power supply voltages have been reduced and become more sensitive to temperature fluctuations and fabrication tolerances. As the power supply voltage is reduced it becomes more challenging to produce a stable bandgap voltage reference. Described herein is a bandgap voltage reference suitable for low power supply voltages.

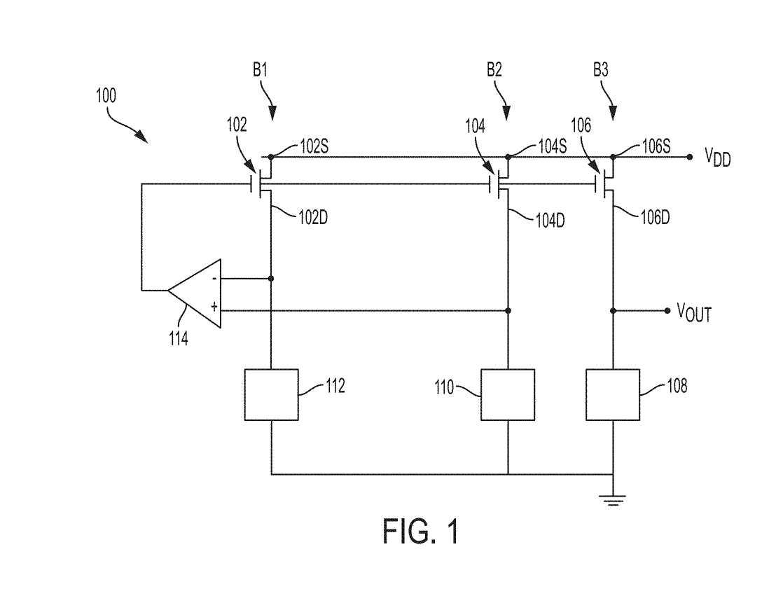

FIG. 1 shows a bandgap voltage reference generator 100. The bandgap voltage reference generator 100 comprises three transistors, 102, 104, and 106, three impedance components, 108, 110, and 112, and an amplifier 114. Transistors 102 and 104 may be of substantially similar sizes. Transistor 106 may be of substantially similar size as transistors 102 and 104 or of a different size proportional to a desired output current. The transistors 102, 104, and 106 may be field-effect transistors (FETs), bipolar junction transistors (BJTs) or any other suitable types of transistors. The impedance components 108, 110, and 112 may include any of transistors, diodes, resistors or any combination thereof. The amplifier 114 may receive the drain voltages 102D and 104D of transistors 102 and 104, respectively, as its two inputs (non-inverting + and inverting −), coupling the drain voltages 102D and 104D to each other at a virtual short. The amplifier 114 may provide its output to the control terminals (e.g., gates) of transistors 102, 104, and 106 to control transistors 102, 104, and 106 based on its output. The bandgap voltage reference generator 100 includes three branches B1, B2 and B3. Branch B1 includes transistor 102 and impedance component 112 connected in series. Branch B2 includes transistor 104 and impedance component 110 connected in series. Branch B3 includes transistor 106 and impedance component 108 connected in series. Each transistor 102, 104, and 106 may allow a current to flow through the series-connected components of its respective branch B1, B2, and B3. In some embodiments, it may be advantageous for the currents in branches B1, B2, and B3 to be approximately equal. Since the gates of the transistors 102, 104, and 106 may be connected to the output of the amplifier 114, the source voltages 102S, 104S, and 106S, of the transistors may be connected to the supply voltage VDD, the drain voltages 102D and 104D of transistors 102 and 104 are coupled to one another through the inputs of the amplifier 114, the currents through transistors 102 and 104, and consequently branches B1 and B2, may be approximately the same. Transistor 106 does not have a drain voltage 106D coupled to amplifier 114. Due to fluctuations in temperature, fabrication tolerances, supply voltage, and/or load, the current through branch B3 may vary relative to the currents in the branches B1 and B3. As a result, though the impedance of impedance component 108 may be constant, fluctuations in the current through transistor 106 on branch B3 may vary the output voltage VOUT.

The output impedance at VOUT may be provided primarily by the drain resistance of transistor 106. However, the scaling down of semiconductor fabrication technology has reduced the size of modern transistors. As a result, if transistor 106 is small, the output impedance at VOUT may be small. The branch B3 on which transistor 106 is connected then may become a weak link for the power supply rejection performance of the bandgap voltage reference generator 100, as fluctuations in the supply voltage VDD may pass easily the output voltage VOUT due to the low impedance of transistor 106.

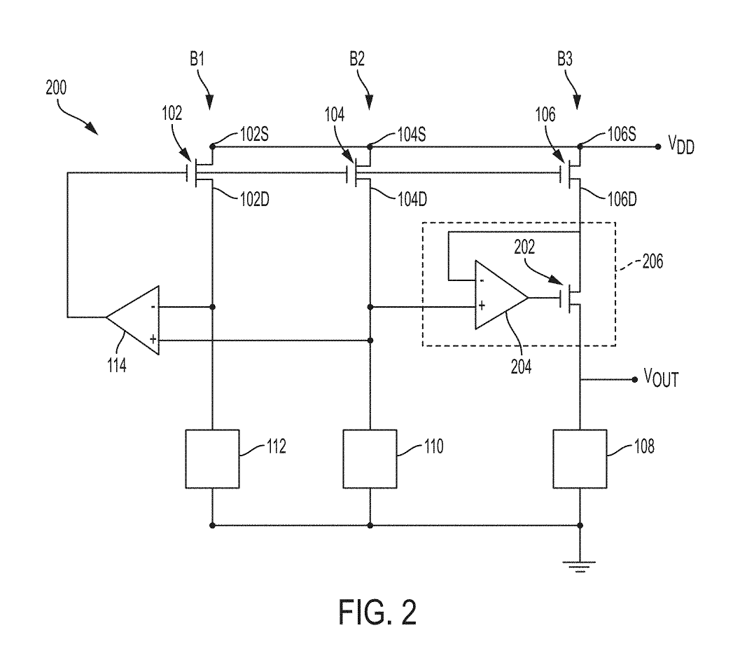

The techniques and circuits described herein enable improving the performance of the bandgap voltage reference generator. FIG. 2 shows an example of a bandgap voltage reference generator 200, according to some embodiments. As shown in FIG. 2, the bandgap voltage reference generator 200 includes a feedback circuit 206. Feedback circuit 206 couples the drain 106D of transistor 106 to the drain 104D of transistor 104 at a virtual short. As a result, the drain voltage of transistor 106 is held approximately equal to the drain voltages of transistors 102 and 104. Further, the feedback circuit may include at least one component between the transistor 106 and VOUT, which can increase the output impedance of the bandgap voltage reference generator 200.

As shown in FIG. 2, the feedback circuit 206 may comprise a transistor 202 connected between transistor 106 and impedance component 108, and an amplifier 204. The gate of transistor 202 may be driven by the output of amplifier 204. The amplifier 204 may have an inverting input connected to the junction between transistors 106 and 202, at 106D. The amplifier 204 may have a non-inverting input connected to the drain of transistor 104, at 104D. In other embodiments, the non-inverting and inverting inputs of amplifier 204 may be reversed; the non-inverting input of amplifier 204 may be connected to the drain of transistor 102, at 102D. Amplifier 204 may force the drain voltage of transistor 106, at 106D, to be approximately equal to the drain voltage of transistor 104, at 104D, which is equal to the drain voltage of transistor 102, at 102D, due to amplifier 114. Any excess voltage caused by fluctuations in temperature or in the value of impedance component 108 may be dropped across transistor 202. The introduction of feedback circuit 206 may improve the accuracy of the output voltage VOUT by more accurately matching the current in transistor 106 with the currents in transistors 102 and 104, as drain voltages 102D, 104D, and 106D are approximately the same. The introduction of transistor 202 may also improve the power supply rejection performance of the bandgap voltage reference generator 200, since transistor 202 is in series with transistor 106, which increases the impedance seen at the output VOUT.

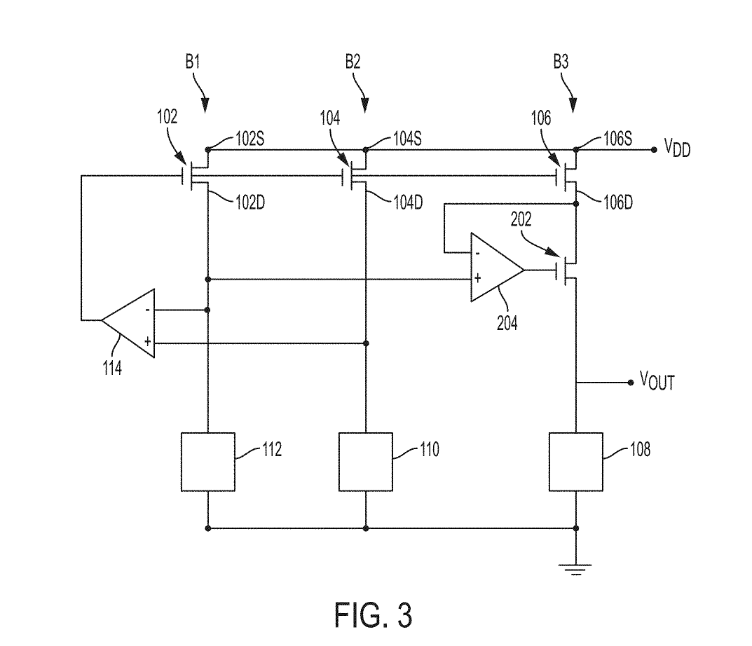

FIG. 3 shows another embodiment of the bandgap voltage reference generator in which the non-inverting input of amplifier 104 is connected to the drain of transistor 102, at 102D, rather than the drain of transistor 104. Since amplifier 114 holds the drains of transistors 102 and 104 at the same voltage, the embodiment of FIG. 3 operates similarly to the embodiment of FIG. 2.

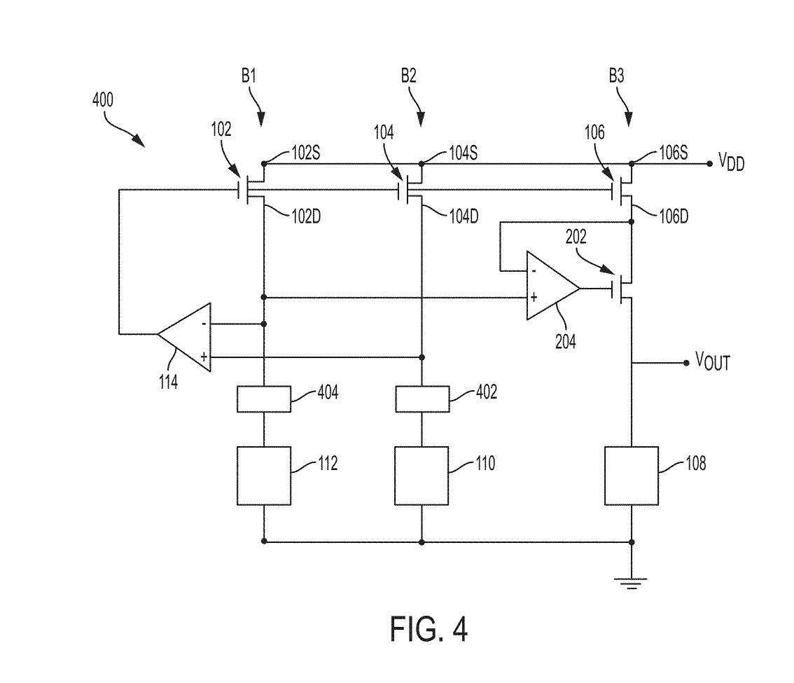

FIG. 4 shows another embodiment of a bandgap voltage reference generator 400, with the addition of impedance components 402 and 404. Impedance components 402 and 404 may be DC level shifting components. Impedance component 402 may be connected between the drain of transistor 104, at 104D, and impedance component 110. Impedance component 404 may be connected between the drain of transistor 102, at 102D, and impedance component 112. The rest of the circuit may be substantially similar to the circuit of FIG. 3. In other embodiments, one input of the amplifier 204 may be tied to the drain of transistor 104, at 104D, instead of transistor 102, at 102D, as shown in the embodiment of FIG. 2. The impedance components 402 and 404 may include any of transistors, diodes, resistors or any combination thereof. While impedance components 402 and 404 are shown as separate from impedance components 110 and 112, in some embodiments the same effect may be obtained by increasing the impedance of impedance components 110 and 112. The DC level shifting impedance components 402 and 404 may increase the drain voltages of transistors 102 and 104, at 102D and 104D respectively. Since the drain voltage of transistor 106, at 106D, may be tied to the drain voltages of transistors 102 and 104, at 102D and 104D, through amplifiers 204 and 114, the drain voltage of transistor 106, at 106D, may increase as well, allowing a higher value of the output reference voltage VOUT to be implemented. The impedance components 404 and 402 may be chosen so that, regardless of the value of the output voltage VOUT to be implemented, there is a sufficient voltage drop across transistor 202.

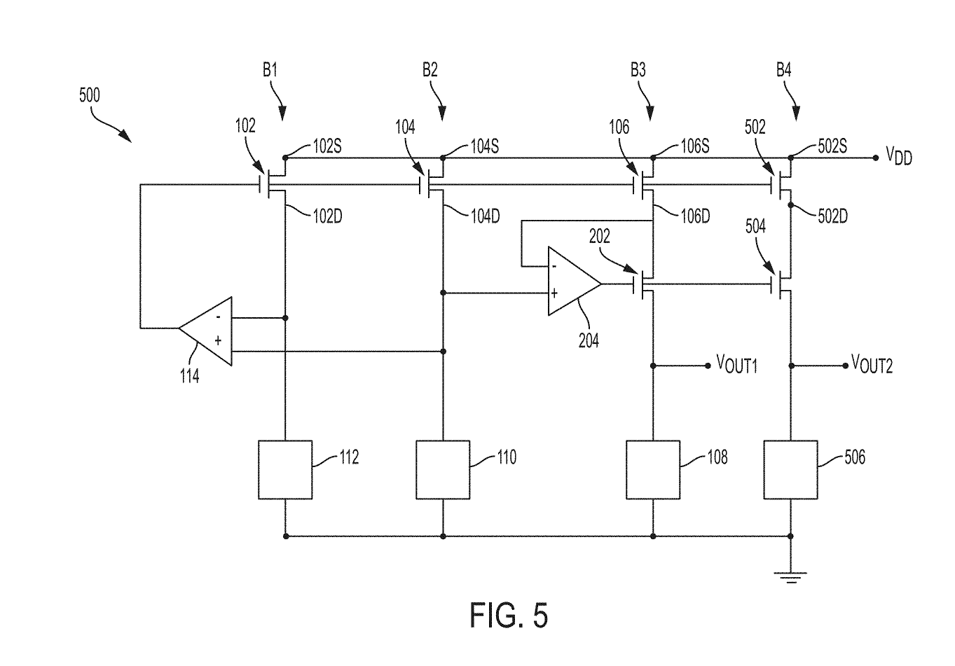

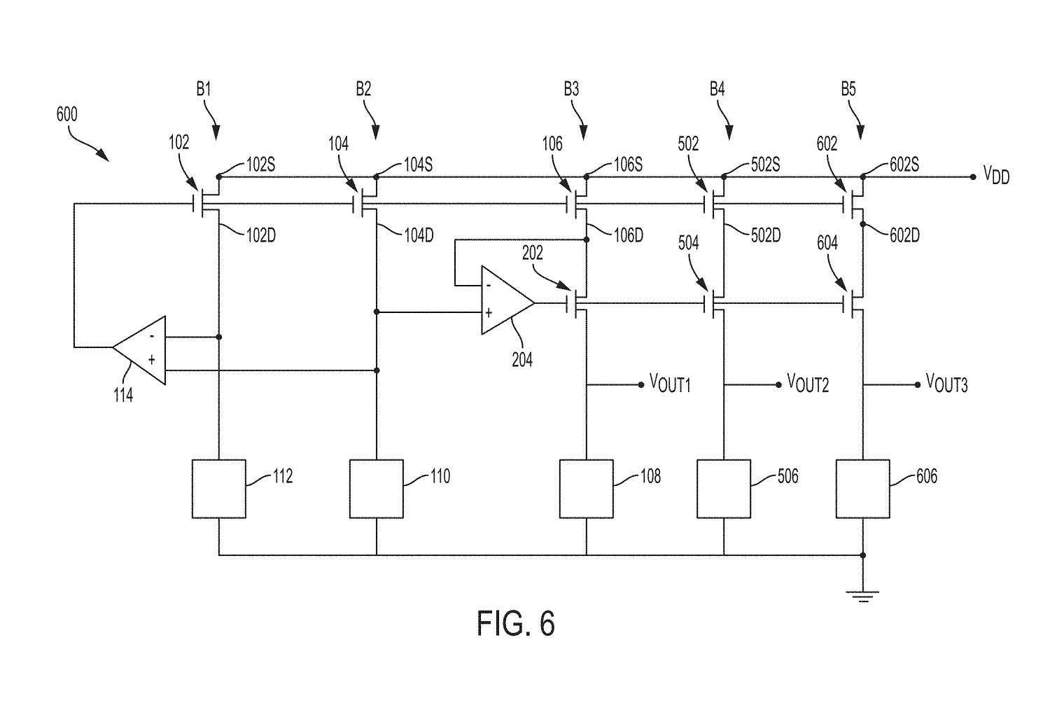

FIG. 5 shows another embodiment of a bandgap voltage reference generator 500 with two output stages. The first output stage may comprise transistors 106 and 202 and impedance component 108, as shown on branch B3 in previous embodiments. The second output stage may comprise two transistors, 502 and 504, and an impedance component 506 in branch B4. The source of transistor 502, at 502S may be connected to the supply voltage VDD, and the gate of transistor 502 may be connected to the gates of transistors 102, 104, and 106 through the output of amplifier 114. The source of transistor 504 may be tied to the drain of transistor 502, at 502D. The gate of transistor 504 may be tied to the gate of transistor 202 through the output of amplifier 204. One input of amplifier 204 is shown as connecting to the drain of transistor 104, at 104D, but in other embodiments may be connected to the drain of transistor 102, at 102D, as shown in FIG. 3. Impedance component 506 is connected between the drain of transistor 504 and a lower reference node, shown in this embodiment as ground. The second output stage may pass a current substantially similar to the current in the first output stage, as the drain and gates of transistors 502 and 106 may be tied, and the gates of transistors 504 and 202 may be tied. As a result, the second output reference voltage VOUT2 may be substantially similar to the first output reference voltage VOUT1. While only two output stages are shown in FIG. 5, in other embodiments any number of additional output stages are possible, with the additional output stages configured and connected in a substantially similar fashion to the second output stage on branch B4, as shown in FIG. 6.

FIG. 6 shows another embodiment of a bandgap voltage reference generator 600. The bandgap voltage reference generator 600 may be the same as or substantially similar to the one of FIG. 5, with an additional output stage shown as branch B5. Branch B5 may comprise transistors, 602 and 604, and an impedance component 606. The source of transistor 602, at 602S, may be connected to the supply voltage VDD, and the gate of transistor 602 may be connected to the gates of transistors 102, 104, 106, and 502 and the output of amplifier 114. The source of transistor 604 may be tied to the drain of transistor 602, at 602D. The gate of transistor 604 may be tied to the gate of transistors 202 and 504 and the output of amplifier 204. One input of amplifier 204 is shown as connecting to the drain of transistor 104, at 104D, but in other embodiments may be connected to the drain of transistor 102, at 102D, as shown in FIG. 3. Impedance component 606 is connected between the drain of transistor 604 and a lower reference node, shown in this embodiment as ground. The third output stage may pass a current substantially similar to the currents in the first output stage and the second output stage, as the drain and gates of transistors 602, 502, and 106 may be tied, and the gates of transistors 604, 504, and 202 may be tied. As a result, the third output reference voltage VOUT3 may be substantially similar to the first output reference voltage VOUT1 and the second output reference voltage VOUT2. While only three output stages are shown in FIG. 6, in other embodiments any number of additional output stages are possible, with the additional output stages configured and connected in a substantially similar fashion to the second output stage on branch B4 and/or the third output stage on branch B5.

In the examples above, the use of the term “substantially similar current” is used on the assumption that the transistors passing the current are of substantially similar sizes. In some embodiments, a transistor of the one or more output stages may be sized relative to transistors 102 and 104 to pass current in the output stage with approximately the same magnitude relative to the currents passed by transistors 102 and 104. For example, if the transistor 106 is approximately twice the size of transistors 102 and 104, transistor 106 may pass a current approximately twice the size of the currents passed by transistors 102 and 104. In embodiments with multiple output stages, such as the one shown in FIG. 5, the transistors of the output stages need not be of the same size. For example, in FIG. 5, transistors 106 and 502 may be of substantially similar sizes to pass substantially similar currents, or of different sizes to pass currents of proportionally different sizes. Furthermore, while the figures herein show PMOS type transistors, NMOS type transistors could also be used by altering the source connections from VDD to Ground. Similarly, other types of transistors could be used, such as bipolar junction type transistors.

Various aspects of the apparatus and techniques described herein may be used alone, in combination, or in a variety of arrangements not specifically discussed in the embodiments described in the foregoing description and is therefore not limited in its application to the details and arrangement of components set forth in the foregoing description or illustrated in the drawings. For example, aspects described in one embodiment may be combined in any manner with aspects described in other embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. A reference voltage generator circuit, comprising:
a first branch having a first transistor, a first impedance in series with the first transistor and a first terminal between the first transistor and the first impedance;
a second branch having a second transistor, a second impedance in series with the second transistor and a second terminal between the second transistor and the second impedance;
a third branch having a third transistor, a third impedance in series with the third transistor, a fourth transistor coupled between the third transistor and the third impedance and a third terminal coupled between the third transistor and the fourth transistor;
a first amplifier having:
a first input coupled to the first terminal;
a second input coupled to the second terminal; and
a first output coupled to respective control terminals of the first, second and third transistors;
a second amplifier having:
a first input coupled to the third terminal; and
a second input coupled to the first terminal or the second terminal; and
a second output coupled to a control terminal of the fourth transistor.

2. The reference voltage generator circuit of claim 1, further comprising:
a fourth branch, the fourth branch comprising a fifth transistor, a fourth impedance in series with the fifth transistor, and a sixth transistor coupled between the fifth transistor and the fourth impedance,
wherein the second output of the second amplifier is coupled to a control terminal of the sixth transistor.

3. The reference voltage generator circuit of claim 1, wherein the first transistor and second transistor are the same size.

4. The reference voltage generator circuit of claim 3, wherein the third transistor is the same size as the first and second transistors.

5. The reference voltage generator circuit of claim 3, wherein the size of the third transistor is different from the size of the first and second transistors.

6. The reference voltage generator circuit of claim 1, wherein the first, second, and third impedances each comprise a transistor, diode, and/or a resistor.

7. The reference voltage generator circuit of claim 1, wherein the first, second and third impedances are connected to a low reference voltage.

8. The reference voltage generator circuit of claim 1, wherein the first branch comprises a first DC level shifting component and the second branch comprises a second DC level shifting component.

9. A reference voltage generator circuit, comprising:
a first branch, having a first current and a first voltage;
a second branch, having a second current and a second voltage;
a third branch, having a third current and a third voltage;
an amplifier that couples the first voltage to the second voltage; and
a feedback circuit that couples the third voltage to at least one of the first or second voltages.

10. The reference voltage generator circuit of claim 9, wherein the first current and second current are the same.

11. The reference voltage generator circuit of claim 10, wherein the third current is the same as the first current and the second current.

12. The reference voltage generator circuit of claim 9, wherein the first branch comprises a first DC level shifting component and the second branch comprises a second DC level shifting component.

13. The reference voltage generator circuit of claim 9, wherein the third branch is a first output branch, and the reference voltage generator circuit further comprises a second output branch.

14. The reference voltage generator circuit of claim 9, wherein the feedback circuit comprises a second amplifier.

15. The reference voltage generator circuit of claim 14, wherein the feedback circuit further comprises a transistor of the second output branch.

16. The reference voltage generator circuit of claim 15, wherein the transistor is controlled by an output of the second amplifier.
